(19) United States
(12) Patent Application Publication
(10) Pub. No.: US 2007/0145492 A1
(43) Pub. Date: Jun. 28, 2007

(54) SEMICONDUCTOR DEVICE AND METHOD OF MANUFACTURE

(76) Inventor: Chee-Hong Choi, Seoul (KR)

Correspondence Address: SHERR & NOURSE, PLLC, 620 HERNDON PARKWAY, SUITE 200, HERNDON, VA, 20170, US

(21) Appl. No.: 11/608,635

(22) Filed: Dec. 8, 2006

(30) Foreign Application Priority Data
Dec. 28, 2005 (KR) 10-2005-0131507

(51) Int. Cl. H01L 23/52; H01L 21/44

(52) U.S. Cl. 257/383; 438/653; 438/656; 438/675; 438/660; 257/751; 257/763; 257/757

(57) ABSTRACT

A method of manufacturing a semiconductor device includes forming an insulating layer over the semiconductor substrate and the gate electrode. An insulating layer may have a via hole connected to the semiconductor substrate or the gate electrode and a trench connected to the via hole. A first barrier layer and a second barrier layer may be formed. The first barrier layer and the second barrier layer may be annealed to form a silicide and combine the first barrier layer and the second barrier layer to form a metal compound.

The present application claims priority under 35 U.S.C. 119 and 35 U.S.C. 365 to Korean Patent Application No. 10-2005-0131507 (filed on Dec. 28, 2005), which is hereby incorporated by reference in its entirety.

### BACKGROUND

In general, a semiconductor device includes a transistor including a source, a drain, and a gate in a device region, which may be defined by a local oxidation of silicon (LOCOS) method or a swallow trench isolation (STI) method. In high speed transistors, the speed of operation depends on low resistance, so silicide may be used in order to reduce the resistance.

A high speed transistor may be formed as follows: A metal layer may be first deposited on a semiconductor substrate including gate, source, and drain regions. Annealing may be performed at a predetermined temperature to form metal silicide. A first insulating layer having a contact hole that exposes the metal silicide may be formed. A first barrier layer is formed on the internal wall of the contact hole, and a plug, which is made of tungsten (W), may be formed to fill the contact hole on the first barrier layer. A second insulating layer having a trench may be formed on the tungsten plug and the first insulating layer, and the trench may be filled with a metal thin film to form metal wiring.

In processes of forming transistors, in order to form metal silicide, a metal layer may be deposited over a semiconductor substrate and an annealing process may be performed. Forming silicide may be a relatively complicated process and may have a strong contribution to costs of manufacturing a semiconductor device.

### SUMMARY

Embodiments relate to a simplified method of manufacturing a semiconductor device. Embodiments relate to a method of manufacturing a semiconductor device A method, in accordance with embodiments, may include at least one of: forming a gate electrode over a semiconductor substrate; forming an insulating layer over a semiconductor substrate and a gate electrode (the insulating layer may have a via hole connected to the semiconductor substrate or the gate electrode and a trench connected to the via hole); forming a barrier layer of titanium (Ti) over the internal walls of a via hole and a trench; forming a barrier layer of tungsten (W) over the barrier layer of titanium (Ti); performing an annealing process over the semiconductor substrate; and forming a metal wiring line to fill the via hole and the trench.

In accordance with embodiments, a semiconductor device includes: a gate electrode formed over a semiconductor substrate; an insulating layer formed over the semiconductor substrate and the gate electrode, the insulating layer having a via hole connected to the semiconductor substrate or the gate electrode and a trench connected to the via hole; a first barrier layer of titanium (Ti) formed over the internal walls of the via hole and the trench; a second barrier layer of tungsten (W) formed over the barrier layer of titanium (Ti); and a metal wiring line for filling the via hole and the trench.

### BRIEF DESCRIPTION OF THE DRAWINGS

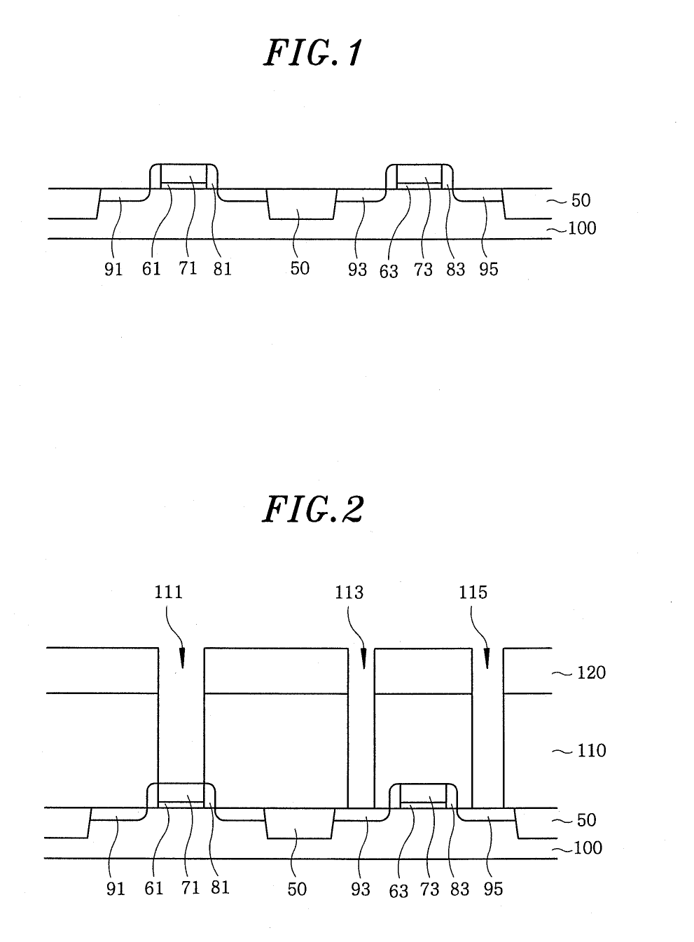

Example FIGS. 1 to 7 are sectional views illustrating processes of manufacturing a semiconductor device, according to embodiments.

### DETAILED DESCRIPTION

In the drawings, the thickness of layers and regions are exaggerated for clarity. The same reference numerals in different drawings represent the same element. It will also be understood that when a layer is referred to as being on another layer, film, region, or substrate, it can be directly on the other layer, film, region, or substrate, or intervening layers may also be present. When a layer is referred to as being directly on another layer, film, region, or substrate, it means that there are no intervening layers.

As illustrated in FIG. 1, gate insulating layer 61, gate insulating layer 63, gate electrode 71, and gate electrode 73 may be formed over semiconductor substrate 100 over which device isolation layer 50 is formed. Spacer 81 and spacer 83 may be formed on the side walls of gate insulating layers 61 and 63 and gate electrodes 71 and 73. Impurity ions are implanted into exposed portions of the semiconductor substrate 100, using the spacers 81 and 83 as masks, to form contact regions 91, 93, and 95 with a high impurity concentration.

As illustrated in FIG. 2, an insulating layer 110 is formed on the entire top surface of the semiconductor substrate 100. A via hole pattern 120 is formed on the insulating layer 110 using a photoresist film. Insulating layer 110 is etched using the via hole pattern 120 to form a first via hole 111 that exposes the gate electrode 71, and second and third via holes 113 and 115 that expose the high impurity concentration contact regions 93 and 95, respectively.

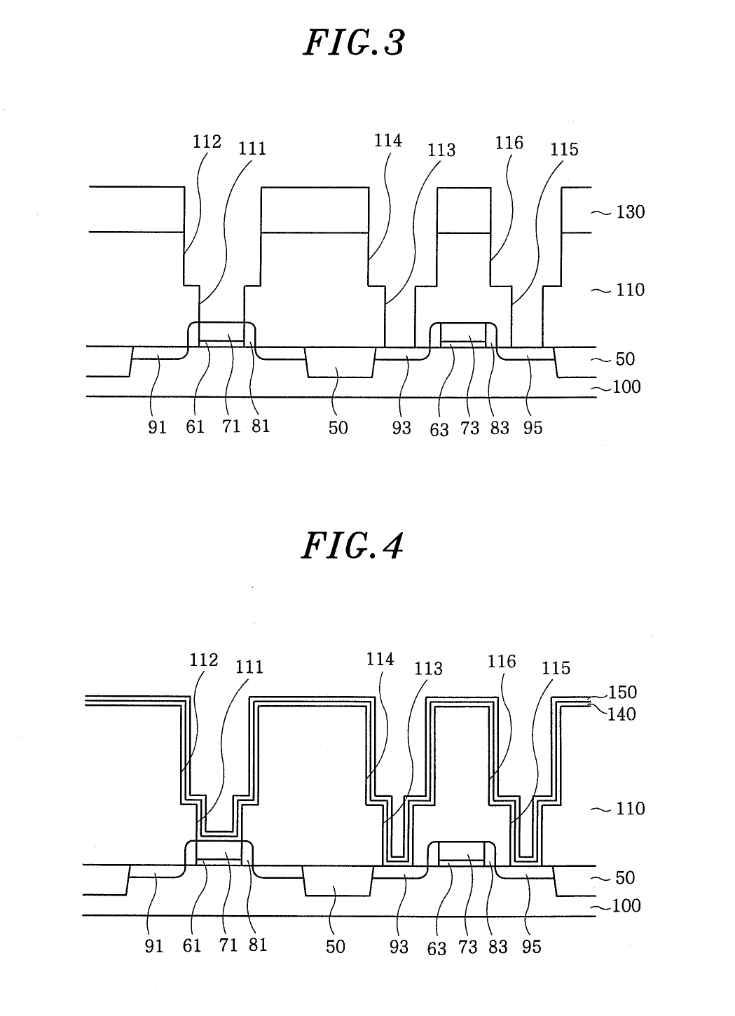

As illustrated in FIG. 3, a trench pattern 130 is formed on the insulating layer 110 using the photoresist film. The insulating layer 110 is etched using the trench pattern 130 as a mask, to thereby form first, second, and third trenches 112, 114, and 116.

As illustrated in FIG. 4, a first barrier metal layer 140 is formed on the exposed gate electrode 71, the semiconductor substrate 100 and the insulating layer 110. A second barrier metal layer 150 is formed on the first barrier metal layer 140.

The first barrier metal layer 140 may be formed of titanium (Ti) and the second barrier metal layer 150 may be formed of tungsten (W). However, one of ordinary skill in the art would appreciate other metals may be used in the barrier layers as appropriate.

As illustrated in FIG. 5, an annealing process is performed. The gate electrode 71 formed of polycrystalline silicon (Si), the first barrier metal layer 140, and the semiconductor substrate 100 formed of silicon (Si) react to each other to create silicides 201, 203, and 205. The first barrier metal layer 140 and the second barrier metal layer 150 react to each other to create a diffusion preventing layer 210 including Titanium-Tungsten (TiW). In accordance with embodiments, since additional processes for forming the silicides 201, 203, and 205 are not necessary, a manufacturing processes may be simplified and costs may be reduced.

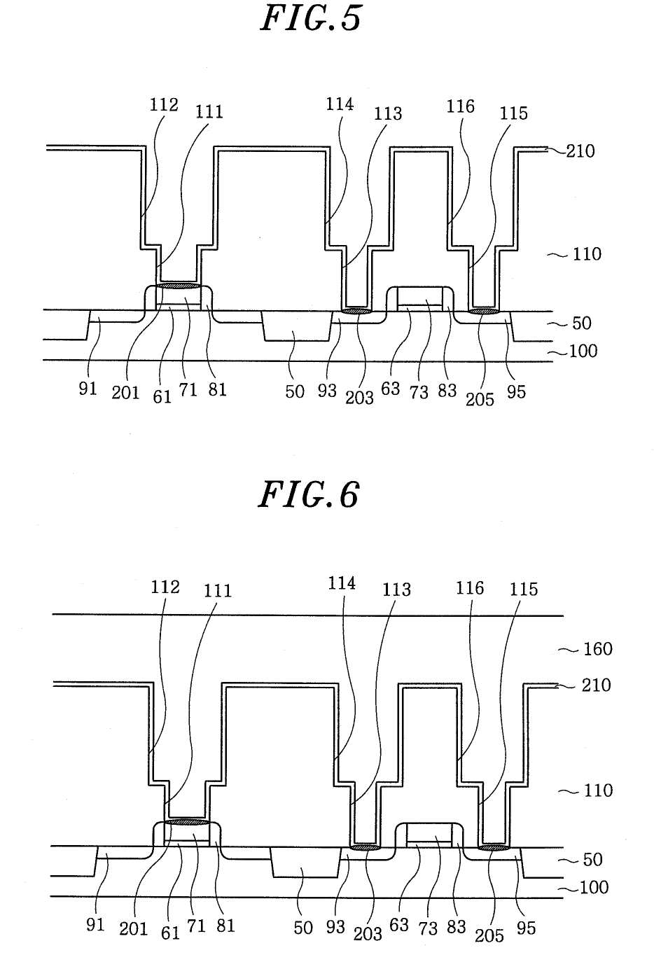

As illustrated in FIG. 6, a metal thin film 160 is formed on the diffusion preventing layer 210. Metal thin film 160 may be formed of copper (Cu).

Through the use of a dual damascene process, the first, second, and third via holes 111, 113, and 115 and the first, second, and third trenches 112, 114, and 116 are filled with copper (Cu). Cu has lower resistance than the tungsten (W). In accordance with embodiments, use of Cu may result in a relatively fast operation speed of a semiconductor device.

The diffusion preventing layer 210 prevents the metal thin film 160 from being diffused into the insulating layer 110, the gate electrode 71, and the semiconductor substrate 100.

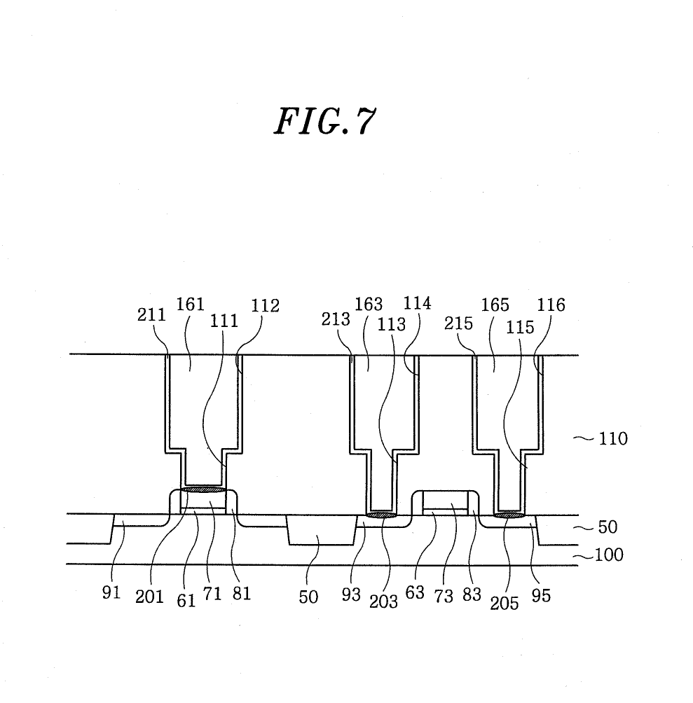

As illustrated in FIG. 7, a chemical mechanical polishing (CMP) process may be performed to planarize the insulating layer 110. At this time, diffusion preventing layers 211, 213, and 215 may exist only in the via holes 111, 113, and 115 and the first, second, and third trenches 112, 114, and 116.

According to embodiments, the via holes and the trenches are formed in the insulating layer using a dual damascene process, and the barrier layer of titanium (Ti) and barrier layer of the tungsten (W) are sequentially formed on the internal walls of the via holes and the trenches. Then the annealing process causes the silicon (Si) of the gate electrode and the semiconductor substrate and the barrier layer of titanium (Ti) to react with each other to form Titanium-Silicide (TiSi). The barrier layer of titanium (Ti) and the barrier layer of tungsten (W) may react with each other to form Titanium-Tungsten (TiW). In accordance with embodiments, since a metal layer does not need to be additionally formed in order to form the silicide, it is possible to simplify the processes of the semiconductor device and to reduce costs of manufacturing a semiconductor device.

It will be apparent to those skilled in the art that various modifications and variations can be made to embodiments. Thus, it is intended that embodiments cover modifications and variations thereof within the scope of the appended claims.

What is claimed is:

1. A method comprising:
forming an insulating layer over a semiconductor substrate;
etching at least one structure in the insulating layer;
forming a first barrier layer over said at least one structure; and
forming a second barrier layer over the first barrier layer, wherein the material of the first barrier layer is different from the material of the second barrier layer.

2. The method of claim 1, wherein the material of the first barrier layer comprises titanium.

3. The method of claim 1, wherein the material of the second barrier layer comprises tungsten.

4. The method of claim 1, wherein said at least one structure comprises at least one of:
at least one via hole; and
at least one trench.

5. The method of claim 4, wherein:
each of said at least one hole exposes at least a portion of one of the semiconductor substrate and a gate electrode; and
said at least one trench is contiguous with said at least one via hole.

6. The method of claim 1, comprising annealing the first barrier layer and the second barrier layer.

7. The method of claim 6, wherein said annealing forms silicide.

8. The method of claim 7, wherein the silicide is titanium silicide

9. The method of claim 7, wherein said silicide is formed in at least one of:
the semiconductor substrate; and
a gate electrode.

10. The method of claim 7, wherein said annealing forms a metal compound from the combination of the first barrier layer and the second metal layer.

11. The method of claim 10, wherein said metal compound is titanium tungsten.

12. The method of claim 6, wherein annealing the first barrier layer and the second barrier layer forms silicide and forms a metal compound from the combination of the first barrier layer and the second metal layer at substantially the same time.

13. The method of claim 1, comprising forming a metal wiring layer to fill said at least one structure.

14. The method of claim 13, wherein the metal wiring layer comprises copper.

15. A semiconductor device comprising:
an insulating layer formed over a semiconductor substrate;
at least one via hole etched in the insulating layer;
at least one trench etched in the insulating layer;
a first barrier layer formed over said at least one structure; and
a second barrier layer formed over the first barrier layer, wherein the material of the first barrier layer is different from the material of the second barrier layer.

16. The semiconductor device of claim 15, wherein at least one of:
the material of the first barrier layer comprises titanium; and
the material of the second barrier layer comprises tungsten.

17. The semiconductor device of claim 15, comprising a gate electrode formed over the semiconductor substrate, wherein:
the insulating layer is formed over the semiconductor substrate and the gate electrode;
each of said at least one hole exposes at least a portion of one of the semiconductor substrate and the gate electrode; and
said at least one trench is contiguous with said at least one via hole.

18. The semiconductor device of claim 15, wherein the first barrier layer and the second barrier layer are annealed to form at substantially the same time:
silicide; and
a metal compound from the combination of the first barrier layer and the second metal layer.

19. The semiconductor device of claim 15, comprising a metal wiring layer in at least one of said at least one via hole and said at least one trench.

20. The semiconductor device of claim 19, wherein the metal wiring layer comprises copper.
